(19) United States
(12) Patent Application Publication
(10) Pub. No.: US 2007/0221825 A1
(43) Pub. Date: Sep. 27, 2007

(54) IMAGING APPARATUS WITH RESOLUTION ADJUSTABILITY

(75) Inventor: Jun Chen, Jiangsu Province (CN)

Correspondence Address: THOMAS, KAYDEN, HORSTEMEYER & RISLEY, LLP, 100 GALLERIA PARKWAY, NW, STE 1750, ATLANTA, GA, 30339-5948, US

(73) Assignee: BENQ CORPORATION, Taoyuan Shien (TW)

(21) Appl. No.: 11/686,527

(22) Filed: Mar. 15, 2007

(30) Foreign Application Priority Data
Mar. 27, 2006 (TW) 95110578

(51) Int. Cl. H01L 27/00

(52) U.S. Cl. 250/208.1

(57) ABSTRACT

An imaging apparatus with resolution adjustability is provided. The imaging apparatus comprises an image sensor and a prism assembly. The prism assembly guides the imaging beam to the image sensor. The prism assembly comprises a first prism and a second prism. The second prism moves between a first position and a second position relative to the first prism. The vertex angle direction of the first prism differs from that of the second prism by 180 degrees. As the second prism is in the first position relative to the first prism, the imaging beam forms an image within a first area of the image sensor through the first prism and the second prism. As the second prism is in the second position relative to the first prism, the imaging beam forms an image within a second area of the image sensor through the first and the second prism.

This application claims the benefit of Taiwan application Serial No. 95110578, filed Mar. 27, 2006, the subject matter of which is incorporated herein by reference.

### BACKGROUND OF THE INVENTION

1. Field of the Invention

The invention relates in general to an imaging apparatus with resolution adjustability, and more particularly to an imaging apparatus with resolution adjustability in which prisms of a prism assembly moveable relative to each other are designed to guide an imaging beam to form an image within different areas of an image sensor.

2. Description of the Related Art

Ordinary image acquisition devices sense a light signal from a to-be-sensed image by a charge couple device (CCD) sensor first, converts the light signal into an image signal by a shift register, and then transmits the image signal to a subsequent analog signal processing circuit for further processing. T0 achieve the object of high resolution, an image sensor having a staggered sensing structure is disclosed in U.S. Pat. No. 4,438,457, and the CCD sensor with the staggered sensing structure has been widely used now.

Referring to FIG. 1, a diagram of a CCD line array sensor with a conventional staggered sensing structure is shown. As indicated in FIG. 1, the CCD line array sensor 100 comprises an odd-numbered sensor assembly 101 and an even-numbered sensor assembly 102, wherein the resolution of the odd-numbered sensor assembly 101 and the resolution of the even-numbered sensor assembly 102 are both 600 dots per inch (dpi), and the length is exemplified by 9 inches. The arrangement of the light-sensing points D1, D3 . . . D10799 of the odd-numbered sensor assembly 101 and the light-sensing points D2, D4 . . . D10800 of the even-numbered sensor assembly 102 constitute the so-called staggered sensing structure.

When image acquisition is performed by an ordinary scanner, the CCD line array sensor 100 is exposed such that the odd-numbered sensor assembly 101 and the even-numbered sensor assembly 102 simultaneously sense a light signal of the to-be-sensed image, then the light-sensing points D1, D3 . . . D10799 and the light-sensing points D2, D4 . . . D10800 generate corresponding signal charges S1, S3 . . . S10799 and S2, S4 . . . S10800, respectively. The subsequent circuit receives the signal charges S1 to S10800 and accordingly generates corresponding image signals. Through the staggered sensing structure of the light-sensing points D1, D3 . . . D10799 and the light-sensing points D2, D4 . . . D10800, the resolution of the captured image is increased to 1200 dpi because of doubling the amount of signal charges obtained by using the odd-numbered sensor assembly 101 or the even-numbered sensor assembly 102 only.

That is, through the staggered sensing structure, the CCD line array sensor 100 can use a sensing assembly with a lower resolution (like 600 dpi) to obtain a higher image resolution (like 1200 dpi). However, in the case of fixing the odd-numbered sensor assembly 101 and the even-numbered sensor assembly 102 mechanically, the highest image resolution is fixed accordingly. Meanwhile, due to the manufacturing technology and cost, the increase in image resolution achieved by staggered sensing structure is certainly limited.

Although the odd-numbered sensor assembly 101 and the even-numbered sensor assembly 102 are closely arranged, the signal charges S1, S3 . . . S10799 and S2, S4 . . . S10800 are actually obtained by different scan lines respectively. However, the CCD line array sensor 100 still considers the signal charges as being obtained by the same scan line and processes the signal charges accordingly. Therefore, an increase in resolution results in an error between the sensed image and the original to-be-sensed image. Moreover, the plane array sensor cannot use the above staggered sensing structure to increase image resolution.

### SUMMARY OF THE INVENTION

The invention is directed to an imaging apparatus with resolution adjustability. The imaging apparatus with resolution adjustability in which prisms of a prism assembly moveable relative to each other are designed to guide an imaging beam to form an image within different areas of an image sensor. Therefore, the imaging apparatus can save the number of sensing assemblies and use a plane array sensor; meanwhile the error between a sensed image and a to-be-sensed image is prevented.

According to a first aspect of the present invention, an imaging apparatus with resolution adjustability is provided. The imaging apparatus comprises an image sensor and a prism assembly. The prism assembly is for guiding the imaging beam to the image sensor. The prism assembly comprises a first prism and a second prism. The second prism is moveable between a first position and a second position relative to the first prism. The vertex angle direction of the first prism differs from the vertex angle direction of the second prism by 180 degrees. As the second prism is in the first position relative to the first prism, the imaging beam forms an image within a first area of the image sensor through the first prism and the second prism. As the second prism is in the second position relative to the first prism, the imaging beam forms an image within a second area of the image sensor through the first prism and the second prism

The invention will become apparent from the following detailed description of the preferred but non-limiting embodiments. The following description is made with reference to the accompanying drawings.

### BRIEF DESCRIPTION OF THE DRAWINGS

FIG. 1 (Prior Art) is a diagram of a CCD line array sensor of a conventional staggered sensing structure.

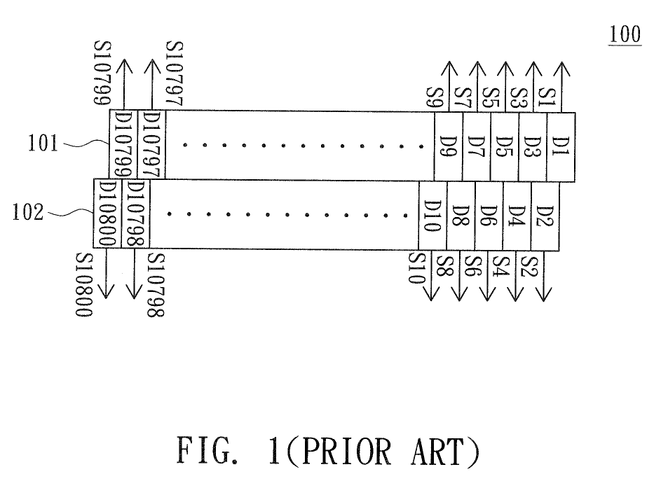

FIG. 2 is a diagram of an imaging apparatus according to a preferred embodiment of the invention.

FIG. 3 is a diagram showing relative shift between two prisms 221 and 222 according to a first embodiment of the invention.

FIG. 4 is a timing diagram of the shift of a prism and the exposure by an image sensor according to a first embodiment of the invention.

FIG. 5A is another diagram showing relative shift between two prisms 221 and 222 according to a first embodiment of the invention.

FIG. 5B is a further diagram showing relative shift between two prisms 221 and 222 according to a first embodiment of the invention.

FIG. 6 is a diagram showing the relative shift between the prisms according to a second embodiment of the invention.

FIG. 7 is a diagram of an imaging area of the image sensor 210 of FIG. 6.

FIG. 8 is a timing diagram of the shift of a prism and the exposure by an image sensor according to a second embodiment of the invention.

FIG. 9 is another diagram showing relative shift between two prisms 221 and 222 according to a second embodiment of the invention.

### DETAILED DESCRIPTION OF THE INVENTION

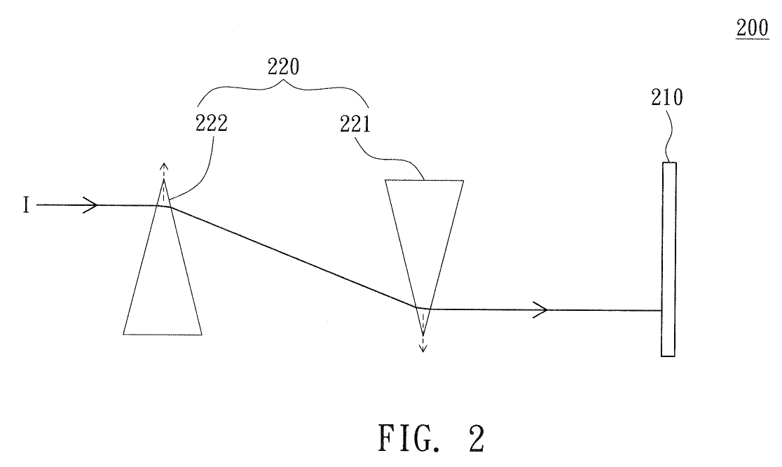

Referring to FIG. 2, a diagram of an imaging apparatus according to a preferred embodiment of the invention is shown. The imaging apparatus 200 comprises an image sensor 210 and a prism assembly 220. Examples of the image sensor 210 include a charge coupling device (CCD), a complementary metal-oxide semiconductor (CMOS) or any light sensor capable of sensing luminance of the light. The prism assembly 220 is used for guiding an imaging beam I to the image sensor 210 and comprises a first prism 221 and a second prism 222. In FIG. 2, the first prism 221 is disposed between the second prism 222 and the image sensor 210. The first prism 221 and the second prism 222 are exemplified by a wedge prism, and the vertex angle direction of the first prism 221 differs from the vertex angle direction of the second prism 222 by 180 degrees as indicated by two dotted arrows in FIG. 2, such that the imaging beam I passing through the first prism 221 and the second prism 222 will not result in dispersion.

In addition, the following two embodiments disclose how the imaging beam I is guided to form an image within different areas on the light-sensing surface of the image sensor 210 according to the relative movement between the prisms of the prism assembly 220. However, the technology of the invention is not limited thereto.

### First Embodiment

In the first embodiment, the image sensor 210 is exemplified by a line array sensor. Meanwhile, the imaging apparatus 200 can be used in an ordinary scanner. The imaging apparatus 200 further comprises a lens (such as a lens assembly) for focusing the imaging beam 1. The prism assembly 220 is disposed between the lens and the image sensor 210; or, the lens is disposed between the prism assembly 220 and the image sensor 210. In the first embodiment, the prism assembly 220 is disposed between the lens and the image sensor 210 to guide the imaging beam I focused by passing through the lens.

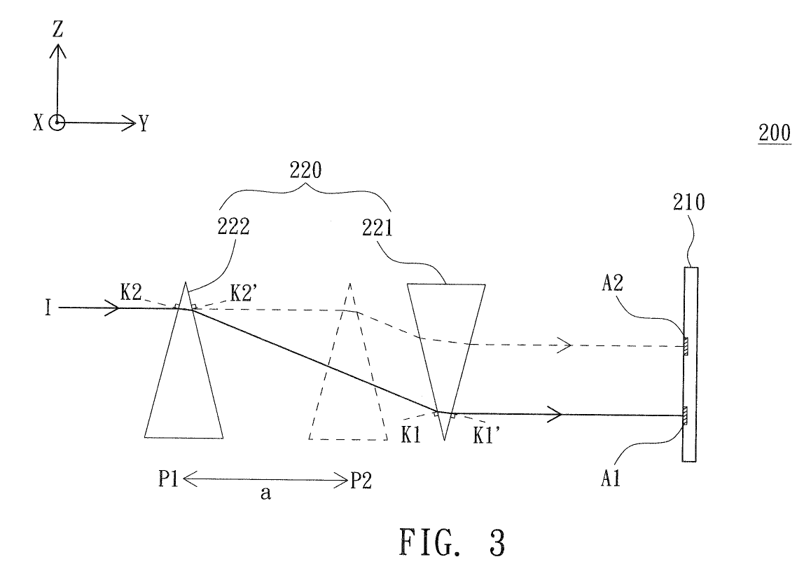

Referring to FIG. 3, a diagram showing relative movement between two prisms 221 and 222 according to a first embodiment of the invention is shown. In FIG. 3, the lens is not shown, and the +X axis is in the direction normal to the paper. As indicated in FIG. 3, the image sensor 210 is disposed along the direction of the Z axis, and the sensing area thereof is parallel to the X-Z plane and toward the direction of the −Y axis. Similarly, the first prism 221 is disposed between the second prism 222 and the image sensor 210. The second prism 222 is moveable between the first position P1 and the second position P2 relative to the first prism 221 as indicated by a double arrow a along the Y axis in FIG. 3. Thus, as the second prism 222 is in the first position P1 relative to the first prism 221, the imaging beam I passing through the first prism 221 and the second prism 222 forms an image within a first area A1 of the image sensor 210. As the second prism 222 moves to the second position P2 relative to the first prism 221, the imaging beam I passing through the first prism 221 and the second prism 222 forms an image within a second area A2 of the image sensor 210. That is, with the relative movement between two prisms 221 and 222 along the Y axis, the imaging beam I can be guided to form an image within different areas of the image sensor 210 along the direction of the Z axis. Meanwhile, piezoelectric materials can be used to achieve a precise control of the movement of the second prism 222, such that the interval between the first area A1 and the second area A2 is only half the dimension of the light-sensing point in the image sensor 210, hence doubling the image resolution.

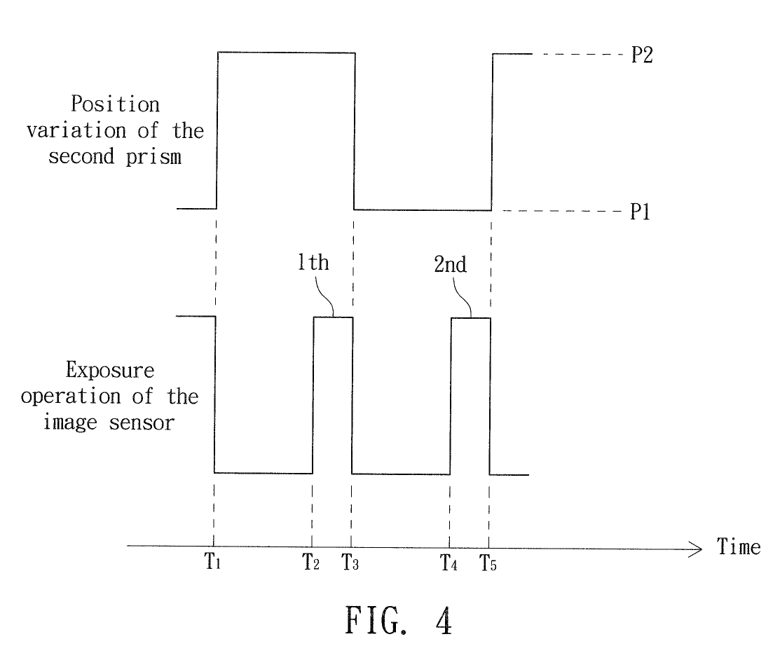

Referring to FIG. 4, a timing diagram of the movement of a prism and the exposure by an image sensor according to a first embodiment of the invention is shown. As indicated in FIG. 4, the second prism 222 starts to move from the first position P1 at the time point T1 and reaches the second position P2 steadily by the time point T2. From the time point T2 to the time point T3, the imaging beam I forms an image at the second area A2, and the image sensor 210 performs the first exposure so as to convert the light signal into an electro-signal. After the first exposure is completed, the second prism 222 starts to move from the second position P2 at the time point T3, and steadily reaches the first position P1 by the time point T4. From the time point T4 to the time point T5, the imaging beam I forms an image at the first area A1, and the image sensor 210 performs the second exposure. After the electro-signals converted during the two exposures are received by the subsequent circuit, the resolution level of the sensed image is increased. However, the exposure timing described in FIG. 4 is only for the purpose of exemplification. The order of the two exposures by the same scan line can be adjusted according to actual needs, and so is the order of exposure and movement.

Besides, when the imaging beam I enters the first prism 221 and the second prism 222, the imaging beam I is angulated with respect to the normal K1 of the incident plane of the first prism 221 and the normal K2 of the incident plane of the second prism 222 respectively as indicated in FIG. 3, lest a portion of the imaging beam I might be reflected back to the lens (that results in interference) along the light axis as the imaging beam I enters the second prism 222. When the imaging beam I is emitted from the first prism 221 and the second prism 222, the imaging beam I is angulated with respect to the normal K1′ of the light-emitting plane of the first prism 221 and the normal K2′ of the light-emitting plane of the second prism 222 respectively as indicated in FIG. 3, lest a portion of the imaging beam I might be reflected back to the second prism 222 (that results in interference) along the light axis as the imaging beam I enters the first prism 221. Such design can also be used between other prisms or between a prism and the image sensor 210 to avoid the reflection interference among the optical devices on the light axis such that a better imaging effect is achieved. Preferably, the imaging beam I entering the second prism 222 is perpendicular to a plane defined by the vertex angle direction of the second prism 222; that is, the X-Z plane which the vertex angle direction of the second prism 222 is in.

As long as the movement of the second prism 222 between the first position P1 and the second position P2 relative to the first prism 221 has a movement component perpendicular to the vertex angle direction plane of the first prism 221 or the second prism 222, the imaging beam I can be guided to form an image within different areas of the image sensor 210 along the direction of the Z axis as indicated in FIG. 3. The movement of the second prism 222 between the first position P1 and the second position P2 relative to the first prism 221 as indicated by the arrow a of FIG. 3 (that is the movement along the Y axis as indicated in FIG. 3) only has a movement component perpendicular to the vertex angle direction plane of the first prism 221 or the second prism 222.

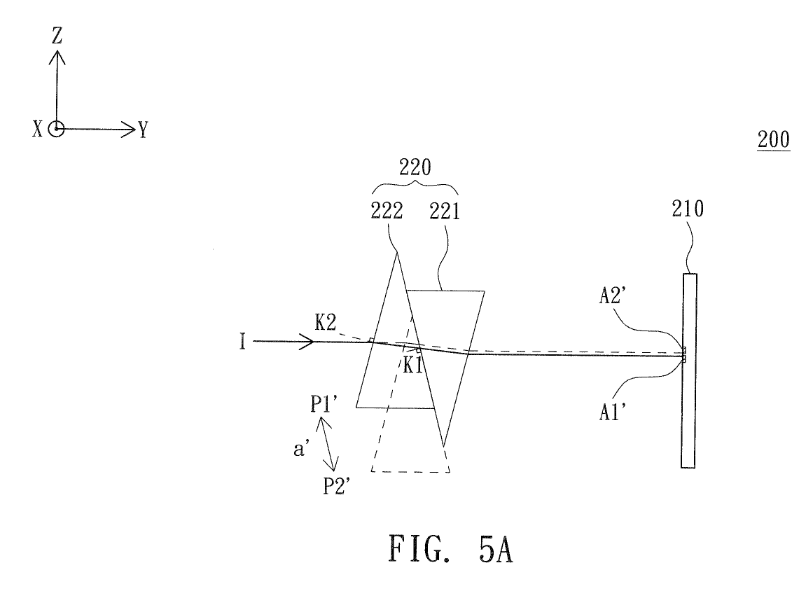

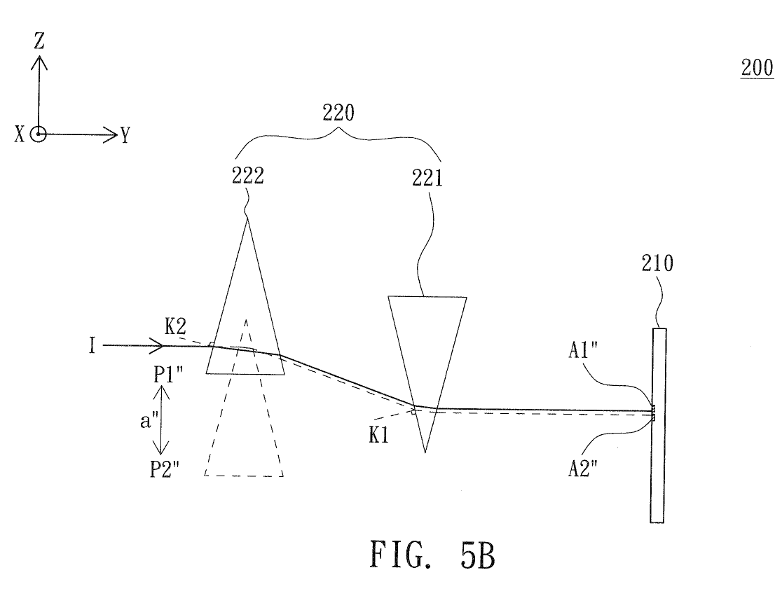

Referring to FIG. 5A, another diagram showing relative movement between two prisms 221 and 222 according to a first embodiment of the invention is shown. FIG. 5A differs from FIG. 3 in that the first prism 221 and the second prism 222 contact each other, and the second prism 222 is moveable between the first position P1′ and the second position P2′ along the contacting surface relative to the first prism 221 as indicated by a double arrow a′ in FIG. 5A. On one hand, the movement of the second prism 222 is thereby more stable; on the other hand, the movement of the second prism 222 between the first position P1′ and the second position P2′ relative to the first prism 221 has a movement component parallel to the vertex angle direction of the first prism 221 or the second prism 222. Moreover, in FIG. 5A, the movement of the second prism 222 between the first position P1′ and the second position P2′ relative to the first prism 221 is further parallel to a lateral surface of the second prism 222, because the movement component along the X axis does not make a contribution to the deflection of the light path. Likewise, when the imaging beam I enters the first prism 221 and the second prism 222, the imaging beam I is angulated with respect to the normal K1 of the incident plane of the first prism 221 and the normal K2 of the incident plane of the second prism 222 respectively. Such design not only reduces the reflection interference between the optical devices on the light axis but also considers the contact of two prisms. Because the first prism 221 and the second prism 222 that contact each other are similar to a parallel transparent plate, and the deflection of the imaging beam I is determined by the incident angle and the thickness and index of refraction of the parallel transparent plate. Meanwhile, the relative movement between two prisms, which contact each other, can vary the thickness of the parallel transparent plate.

Thus, as the second prism 222 is in the first position P1′ relative to the first prism 221, the imaging beam I passing through the first prism 221 and the second prism 222 forms an image within a first area A1′ of the image sensor 210; as the second prism 222 is in the second position P2′ relative to the first prism 221, the imaging beam I passing through the first prism 221 and the second prism 222 also forms an image within a second area A2′ of the image sensor 210. That is, through the relative movement between two prisms that contact each other, the imaging beam I can be guided to form an image within different areas along the direction of the Z axis of the image sensor 210. Meanwhile, piezoelectric materials can be used to achieve a precise control of the movement of the second prism 222, such that the interval between the first area A1′ and the second area A2′ is only half the dimension of the light-sensing point in the image sensor 210, hence doubling the resolution level.

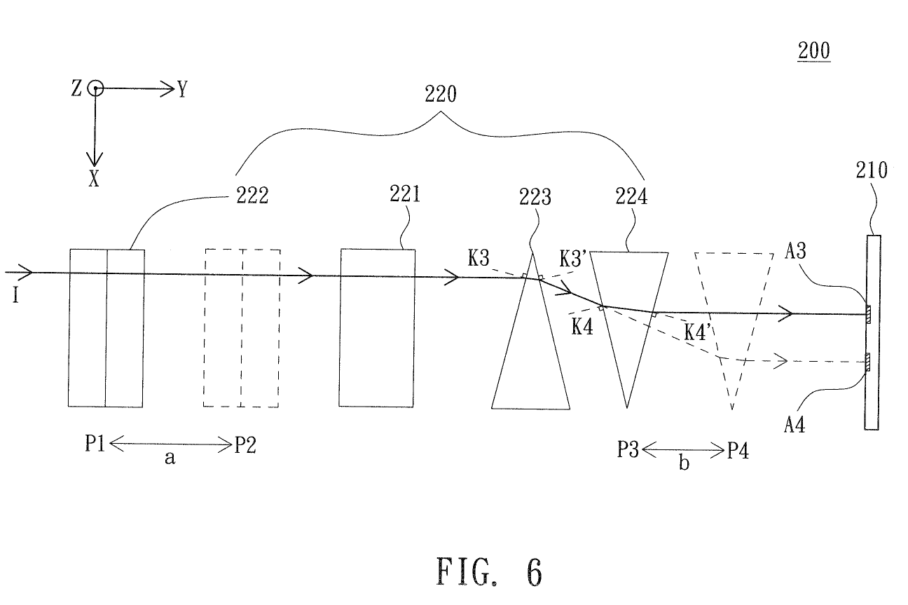

Referring to FIG. 5B, a further diagram showing relative movement between two prisms 221 and 222 according to a first embodiment of the invention is shown. FIG. 5B differs from FIG. 5A in that the two prisms 221 and 222 of FIG. 5B does not contact each other. As indicated in FIG. 5B, as long as the movement of the second prism 222 between the first position P1′ and the second position P2′ relative to the first prism 221 has a movement component parallel to the vertex angle direction of the first prism 221 or the second prism 222, the position variation of the imaging area as indicated in FIG. 6A can also be achieved.

### Second Embodiment

In the second embodiment, the image sensor 210 is exemplified by a plane array sensor. Meanwhile, the imaging apparatus 200 can be used in an ordinary digital camera comprising a lens (such as a lens assembly) for focusing the imaging beam 1. In the second embodiment, the prism assembly 220 is disposed between the lens and the image sensor 210.

Referring to FIG. 6, a diagram showing the relative movement between the prisms according to a second embodiment of the invention is shown. In FIG. 6, the directions of the X axis, the Y axis and the Z axis are the same with that in FIG. 3. Meanwhile, the direction of the Z axis is normal to the paper, and the sensing area of the image sensor is parallel to the X-Z plane and toward the direction of the −Y axis. Moreover, FIG. 6 differs from FIG. 3 in that the prism assembly 220 further comprises a third prism 223 and a fourth prism 224 as indicated in FIG. 6. Like the first prism 221 and the second prism 222, the third prism 223 and the fourth prism 224 can be wedge prisms, and the vertex angle direction of the third prism 223 also differs from the vertex angle direction of the fourth prism 224 by 180 degrees, such that the imaging beam I passing through the third prism 223 and the fourth prism 224 will not result in dispersion. In the present embodiment of the invention, the fourth prism 224 is disposed between the third prism 223 and the image sensor 210, and the third prism 223 and the fourth prism 224 are disposed between the first prism 221 and the image sensor 210.

In the first embodiment, the relative movement between the first prism 221 and the second prism 222 functions to guide the imaging beam I to form an image within different areas of the image sensor 210 along the direction of the Z axis, hence achieving one dimensional (the Z axis) control. When the image sensor 210 is a plane array sensor (the X-Z plane), the third prism 223 and the fourth prism 224 are used to increase one more dimensional (the X axis) control, such that the imaging beam I passing through the prism assembly 220 can form an image within different areas of the image sensor 210 along the X-Z plane. According to the principle of vector addition, when the predetermined angle between the vertex angle direction of the second prism 222 and the vertex angle direction of the fourth prism 224 is larger than 0 degree but smaller than 180 degrees, two dimensional control is achieved. In the second embodiment, the vertex angle direction of the second prism 222 is pointed towards the +Z axis while the vertex angle direction of the fourth prism 224 is pointed towards the +X axis, so the predetermined angle is 90 degrees as indicated in FIG. 6.

Meanwhile, the fourth prism 224 is moveable between the third position P3 and the fourth position P4 relative to the third prism 223 as indicated by a double arrow b in FIG. 6. Thus, as the fourth prism 224 is in the third position P3 relative to the third prism 223, the imaging beam I passing through the third prism 223 and the fourth prism 224 forms an image within a third area A3 of the image sensor 210; as the fourth prism 224 is in the fourth position P4 relative to the third prism 223, the imaging beam I passing through the third prism 223 and the fourth prism 224 forms an image within a fourth area A4 of the image sensor 210. That is, through the relative movement between the third prism 223 and the fourth prism 224, the imaging beam I can be guided to form an image within different areas of the image sensor 210 along the direction of the X axis. Meanwhile, piezoelectric materials can be used to achieve a precise control of the movement of the fourth prism 224, such that the interval between the third area A3 and the fourth area A4 is only half the dimension of the light-sensing point in the image sensor 210. With the relative movement of the same scale applied between the first prism 221 and the second prism 222, two dimensional control is achieved, and the resolution level is increased by four times.

The third area A3 and the fourth area A4 mentioned above are relative, not two fixed areas. For example, the third area A3 and the fourth area A4 as the second prism 222 is in the first position P1 relative to the first prism 221 differ with the third area A3 and the fourth area A4 as the second prism 222 is in the second position P2 relative to the first prism 221 in the position of the image sensor 210 along the direction of the Z axis. Likewise, the first area A1 and the second area A2 are relative as well. The relative changes in the first area to the fourth area which occur when the four prisms 221, 222, 223 and 224 move relatively are elaborated below with accompanied drawings.

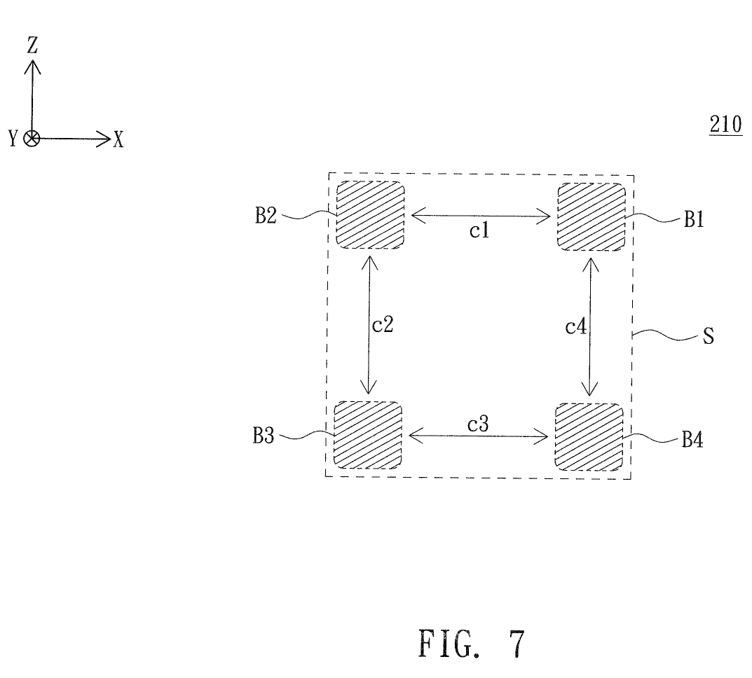

Referring to FIG. 7, a diagram of an imaging area of the image sensor 210 of FIG. 6 is shown. In FIG. 7, the direction of the +Y axis penetrates the paper. Through the relative movement among the four prisms 221, 222, 223 and 224, the image formed by the imaging beam I mostly fail within a region S on the image sensor 210. The shape of the region S is related to the predetermined angle between the vertex angle direction of the second prism 222 and the vertex angle direction of the fourth prism 224. In the second embodiment, when the predetermined angle is 90 degrees, the region S is a rectangle.

As indicated in FIG. 7, as the second prism 222 and the fourth prism 224 are in the second position P2 and the fourth position P4 respectively, the imaging beam I form an image within an area B1. As the second prism 222 and the fourth prism 224 are in the second position P2 and the third position P3 respectively, the imaging beam I forms an image within an area B2. As the second prism 222 and the fourth prism 224 are in the first position P1 and the third position P3 respectively, the imaging beam I forms an image within an area B3. As the second prism 222 and the fourth prism 224 are in the first position P1 and the fourth position P4 respectively, the imaging beam I forms an image within an area B4.

Thus, by controlling the second prism 222 to move between the first position P1 and the second position P2, the image formed by the imaging beam I moves reciprocally between the first area A1 and the second area A2, as indicated by the double arrows c2 and c4 in FIG. 7, the first area A1 and the second area A2 correspond to the areas B3 and B2 or the areas B4 and B1 in FIG. 7. On the other hand, by controlling the fourth prism 224 to move between the third position P3 and the fourth position P4, the image formed by the imaging beam I moves reciprocally between the third area A3 and the fourth area A4, as indicated by the double arrows c1 and c3 in FIG. 7, the third area A3 and the fourth area A4 correspond to the areas B2 and B1 or the areas B3 and B4 in FIG. 7.

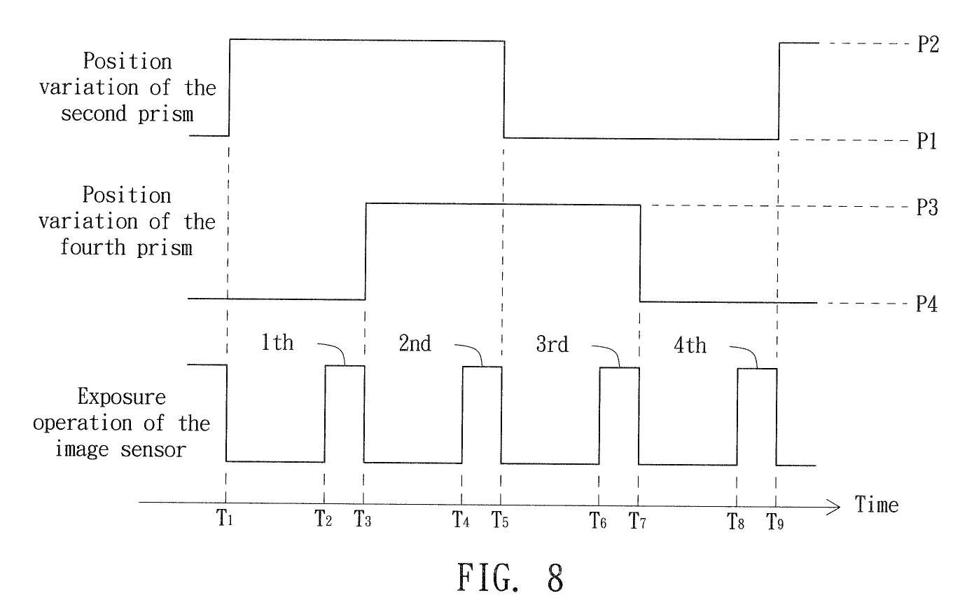

Referring to FIG. 8, a timing diagram of the movement of a prism and the exposure by an image sensor according to a second embodiment of the invention is shown. The second prism 222 starts to move from the first position P1 at the time point T1, and reaches the second position P2 steadily by the time point T2. From the time point T1 to the time point T3, the fourth prism 224 is in the fourth position P4. When the imaging beam I forms an image within the area B1 between the time point T2 and the time point T3, the image sensor 210 performs the first exposure so as to convert the light signal into an electro-signal. After the first exposure is completed, the fourth prism 224 starts to move from the fourth position P4 at the time point T3, and steadily reaches the third position P3 by the time point T4. Between the time point T4 to the time point T5, that is, when the imaging beam I forms an image within the area B2, the image sensor 210 performs the second exposure. After the second exposure is completed, the second prism 222 starts to move from the second position P2 at the time point T5, and steadily reaches the first position P1 by the time point T6. From the time point T6 to the time point T7, that is, when the imaging beam I forms an image within area B3, the image sensor 210 performs the third exposure. After the third exposure is completed, the fourth prism 224 starts to move from the third position P3 at the time point T7, and steadily reaches the fourth position P4 by the time point T8. From the time point T8 to the time point T9, that is, when the imaging beam I forms an image within area B4, the image sensor 210 performs the fourth exposure. After the electro-signal converted from the fourth exposure is received by the subsequent circuit, the resolution level of the sensed image is increased by four times. However, the timing sequence of exposure exemplified in FIG. 8 is only an example, the order in the four exposures can be adjusted according to actual needs, and so can the order of exposure and movement be adjusted according to actual needs.

Moreover, when the imaging beam I enters the third prism 223 and the fourth prism 224, the imaging beam I is angulated with respect to the normal K3 of the incident plane of the third prism 223 and the normal K4 of the incident plane of the fourth prism 224, respectively as indicated in FIG. 6. When the imaging beam I is emitted from the third prism 223 and the fourth prism 224, the imaging beam I is also angulated with respect to the normal K3′ of the light-emitting plane of the third prism 223 and the normal K4′ of the light-emitting plane of the fourth prism 224 respectively. Such design can also be used between other prisms or between a prism and the image sensor 210 to avoid the reflection interference among the optical elements on the light axis such that a better imaging effect is achieved. Preferably, the imaging beam I entering third prism 223 is perpendicular to the vertex angle direction plane of third prism 223; that is, the X-Z plane which the vertex angle direction of third prism 223 is in.

Any one who is skilled in the technology of the invention will understand that as long as the movement of the fourth prism 224 between the third position P3 and the fourth position P4 relative to the third prism 223 comprises a movement component perpendicular to the vertex angle direction plane of the third prism 223 or the fourth prism 224, or comprises a movement component parallel to the vertex angle direction of the third prism 223 or the fourth prism 224, the imaging beam I can be guided to form an image within different areas of the image sensor 210 along the direction of the X axis as indicated in FIG. 6. As indicated by the arrow b of FIG. 6, the movement of the fourth prism 224 between the third position P3 and the fourth position P4 relative to the third prism 223 is along the Y axis as indicated in FIG. 6 and only has a movement component perpendicular to the vertex angle direction plane of the third prism 223 or the fourth prism 224.

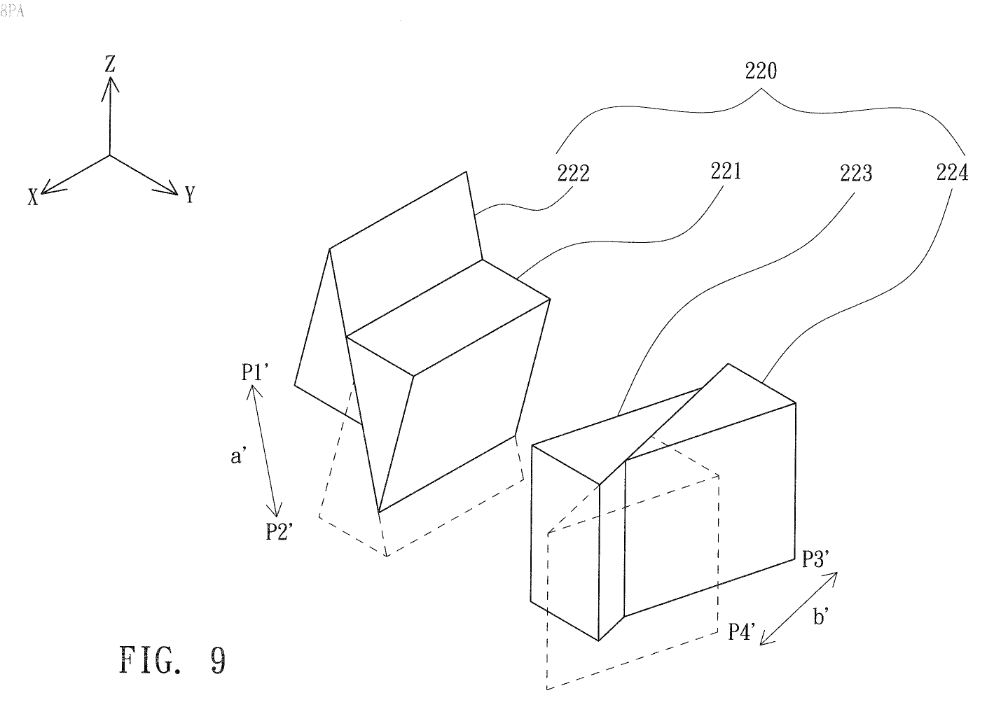

Referring to FIG. 9, another diagram showing relative movement between two prisms 221 and 222 according to a second embodiment of the invention is shown. In FIG. 9, the drawings and numeric designations of the imaging beam I and the image sensor 210 are omitted. In FIG. 9, the first prism 221 and the second prism 222 also contact each other as in FIG. 5A, and the second prism 222 is moveable between the first position P1′ and the second position P2′ along the contacting surface relative to the first prism 221 as indicated by an arrow a′. In addition, FIG. 9 differs from FIG. 6 in that, the third prism 223 and the fourth prism 224 contact each other, and the fourth prism 224 is moveable between the third position P3′ and the fourth position P4′ along the contacting surface relative to the third prism 223 as indicated by an arrow b′. On one hand, the movement of the fourth prism 224 is more stable; on the other hand, the movement of the fourth prism 224 the third position P3′ and the fourth position P4′ relative to the third prism 223 has a movement component parallel to the vertex angle direction of the third prism 223 or the fourth prism 224. Furthermore, in FIG. 9, the movement of the fourth prism 224 between the third position P3′ and the fourth position P4′ relative to the third prism 223 is further parallel to a lateral surface of the fourth prism 224.

Likewise, when the imaging beam I enters the third prism 223 and the fourth prism 224, the imaging beam I is angulated with respect to the normal K3 of the incident plane of the third prism 223 and the normal K4 of the incident plane of the fourth prism 224 respectively. Such design not only reduces the reflection interference among the optical devices on the light axis but also considers the contact of two prisms.

The relative movement between the first prism 221 and the second prism 222 that contact each other as well as the relative movement between the third prism 223 and the fourth prism 224 that contact each other, as indicated in FIG. 7, both function to guide the imaging beam I to form an image within different areas of the image sensor 210 along the X-Z plane. Meanwhile, piezoelectric materials can be used to achieve a precise control of the movement of the second prism 222 and the fourth prism 224, hence increasing the resolution level by four times. However, whether the two prisms 221 and 222 contact each other or the two prisms 223 and 224 contact each other can be respectively designed.

Although the prisms of the first embodiment and the second embodiment are exemplified by wedge prisms, various prisms can be used to achieve the same effect, and the shape of the lateral surface of the wedge prism can be various triangles to fit the needs of manufacturing and usage. Moreover, in the second embodiment, the first prism 221 and the third prism 223 can also contact each other through appropriate arrangement. That is, the first prism 221 and the third prism 223 can be one-piece or a doublet. Besides, by controlling the relative movement between the prisms with more precision, the second prism 222 can be moveable among three or more than three positions relative to the first prism 221, and thereby the resolution level of image can be further increased.

The above effect of one or two dimensional control can be also achieved through the relative movement of the first prism 221 relative to the second prism 222, the relative movement of the third prism 223 relative to the fourth prism 224 or by disposing the first prism 221 and the second prism 222 between the third prism 223 and the fourth prism 224 and the image sensor 210. Meanwhile, the inclination between the imaging beam I and the normal of the incident plane of each prism can be adjusted accordingly. Any design by which the imaging apparatus 200 have prisms of a prism assembly moveable relative to each other, so as to guide the imaging beam I to form an image within different areas of the image sensor 210 to increase resolution level is within the scope of technology of the invention.

Through the relative movement between the prisms of the prism assembly, the imaging apparatus with resolution adjustability disclosed in the above embodiments of the invention guides the imaging beam to form an image within different areas of the image sensor so as to increase resolution level, not only avoiding the error between the sensed image and the to-be-sensed image and without increasing the number of the sensing assembly of the image sensor but also applicable to the plane array sensor. Besides, the above embodiments are exemplified by obtaining one period of image information. However, in practical application, the above embodiments are also applicable to the acquisition of multi-periods of image information.

While the invention has been described by way of example and in terms of a preferred embodiment, it is to be understood that the invention is not limited thereto. On the contrary, it is intended to cover various modifications and similar arrangements and procedures, and the scope of the appended claims therefore should be accorded the broadest interpretation so as to encompass all such modifications and similar arrangements and procedures.

What is claimed is:

1. An imaging apparatus with resolution adjustability, comprising:
an image sensor; and
a prism assembly for guiding an imaging beam to the image sensor, the prism assembly comprising:
a first prism; and
a second prism moveable between a first position and a second position relative to the first prism, wherein a vertex angle direction of the first prism differs from a vertex angle direction of the second prism by 180 degrees;
wherein as the second prism is in the first position relative to the first prism, the imaging beam forms an image within a first area of the image sensor through the first prism and the second prism, and as the second prism is in the second position relative to the first prism, the imaging beam forms an image within a second area of the image sensor through the first prism and the second prism.

2. The imaging apparatus according to claim 1, further comprising a lens, wherein the prism assembly is disposed between the lens and the image sensor.

3. The imaging apparatus according to claim 1, further comprising a lens, wherein the lens is disposed between the prism assembly and the image sensor.

4. The imaging apparatus according to claim 1, wherein the image sensor is a line array sensor.

5. The imaging apparatus according to claim 1, wherein the image sensor performs exposure as the second prism moves to the first position and the second position relative to the first prism.

6. The imaging apparatus according to claim 1, wherein the first prism and the second prism are wedge prisms.

7. The imaging apparatus according to claim 1, wherein when the imaging beam enters the first prism and the second prism, the imaging beam is angulated with respect to the normal of the incident plane of the first prism and the normal of the incident plane of the second prism respectively.

8. The imaging apparatus according to claim 7, wherein the imaging beam entering the second prism is perpendicular to the vertex angle direction plane of the second prism.

9. The imaging apparatus according to claim 1, wherein the shift of the second prism between the first position and the second position relative to the first prism has a movement component perpendicular to the vertex angle direction plane of the first prism or the second prism.

10. The imaging apparatus according to claim 1, wherein the movement of the second prism between the first position and the second position relative to the first prism has a movement component parallel to the vertex angle direction plane of the first prism or the second prism.

11. The imaging apparatus according to claim 10, wherein the movement of the second prism between the first position and the second position relative to the first prism is parallel to a lateral surface of the second prism.

12. The imaging apparatus according to claim 11, wherein the first prism and the second prism contact each other, and when the imaging beam enters the first prism and the second prism, the imaging beam is angulated with respect to the normal of the incident plane of the first prism and the normal of the incident plane of the second prism respectively.

13. The imaging apparatus according to claim 1, wherein the image sensor is a plane array sensor.

14. The imaging apparatus according to claim 13, wherein the prism assembly further comprises a third prism and a fourth prism, the fourth prism is moveable between a third position and a fourth position relative to the third prism, and the vertex angle direction of the third prism differs from the vertex angle direction of the fourth prism by 180 degrees;
wherein when the fourth prism is in the third position relative to the third prism, the imaging beam forms an image within a third area of the image sensor through the third prism and the fourth prism, and when the fourth prism is in the fourth position relative to the third prism, the imaging beam forms an image within a fourth area of the image sensor through the third prism and the fourth prism;
wherein a predetermined angle between the vertex angle direction of the second prism and the vertex angle direction of the fourth prism is larger than 0 degree but smaller than 180 degrees.

15. The imaging apparatus according to claim 14, wherein the predetermined angle is 90 degrees.

16. The imaging apparatus according to claim 14, wherein the image sensor performs exposure as the second prism moves to the first position and the second position relative to the first prism, and when the fourth prism moves to the third position and the fourth position relative to the third prism.

17. The imaging apparatus according to claim 14, wherein the third prism and the fourth prism are wedge prisms.

18. The imaging apparatus according to claim 14, wherein the imaging beam entering the third prism is perpendicular to the vertex angle direction plane of the third prism.

19. The imaging apparatus according to claim 14, wherein the first prism and the third prism are one-piece.

20. The imaging apparatus according to claim 14, wherein the first prism and the third prism form a doublet.

21. The imaging apparatus according to claim 14, wherein the movement of the fourth prism between the third position and the fourth position relative to the third prism has a movement component perpendicular to the vertex angle direction plane of the third prism or the fourth prism.

22. The imaging apparatus according to claim 14, wherein the movement of the fourth prism between the third position and the fourth position relative to the third prism has a movement component parallel to the vertex angle direction of the third prism or the fourth prism.

23. The imaging apparatus according to claim 21, wherein the movement of the fourth prism between the third position and the fourth position relative to the third prism is parallel to a lateral surface of the fourth prism.

24. The imaging apparatus according to claim 23, wherein the first prism and the second prism contact each other, the third prism and the fourth prism contact each other, when the imaging beam enters the first prism and the second prism, the imaging beam is angulated with respect to the normal of the incident plane of the first prism and the normal of the incident plane of the second prism respectively, and when the imaging beam enters the third prism and the fourth prism, the imaging beam is angulated with respect to the normal of the incident plane of the third prism and the normal of the incident plane of the fourth prism respectively.
